(19) United States
(12) Patent Application Publication
(10) Pub. No.: US 2025/0344604 A1
(43) Pub. Date: Nov. 6, 2025

(54) METHOD FOR MANUFACTURING JOINED BODY AND JOINED BODY

(71) Applicant: NGK INSULATORS, LTD., Nagoya-shi (JP)

(72) Inventor: Masato NIWA, Inuyama-shi (JP)

(21) Appl. No.: 19/267,713

(22) Filed: Jul. 14, 2025

Related U.S. Application Data
(63) Continuation of application No. PCT/JP2024/000452, filed on Jan. 11, 2024.

(30) Foreign Application Priority Data
Mar. 16, 2023 (JP) 2023-042431

(51) Int. Cl. H10N 30/072; B32B 9/04

(52) U.S. Cl. CPC H10N 30/072; B32B 9/04; B32B 2250/02

(57) ABSTRACT

Provided is a method for manufacturing a joined body, the method including: an outer peripheral processing step of forming an outer peripheral processed portion, ground inward from an edge portion along a main surface of one of a piezoelectric material substrate and a support substrate; a joining step of joining one of the piezoelectric material substrate and the support substrate, which is formed thereon with the outer peripheral processed portion, to a main surface of the other one, with a main surface side of the one of the piezoelectric material substrate and the support substrate serving as a joining surface side; and a thinning step of thinning the joined piezoelectric material substrate. Therefore, there are provided a joined body etc. in which a corner portion is not formed in an outer peripheral portion and breakage or cracking is less likely to occur in the outer peripheral portion in subsequent steps.

### CROSS-REFERENCE TO RELATED APPLICATION

This application is a continuation application of PCT/JP2024/000452, filed on Jan. 11, 2024, which claims the benefit of priority of Japanese Patent Application No. 2023-042431, filed on Mar. 16, 2023, the entire contents of which are incorporated herein by reference.

### TECHNICAL FIELD

The present invention relates to a method for manufacturing a joined body, and a joined body.

### BACKGROUND ART

For the purpose of realizing a high-performance semiconductor element, for example a structure in which a piezoelectric material substrate and a support substrate are bonded together has been studied. In recent years, in order to realize a further high-performance device, a structure including an intermediate layer or a structure using a support substrate using a difficult-to-process material has been proposed. In order to realize such a structure, it is necessary to bond both the piezoelectric material substrate and the support substrate to each other, but when these substrates are bonded to each other, a non-bonded region (non-bonded portion) is generated in an outer peripheral portion. The non-bonded portion is generated due to the shape of the outer peripheral portion before bonding of these substrates. The shape is called sagging or roll-off. When a non-bonded portion is generated in the outer peripheral portion, peeling easily occurs during processing of the piezoelectric material. In addition, when peeled off, fragments are generated, and the fragments may damage the piezoelectric material. In order to avoid this, a method of performing processing to remove a non-bonded portion generated in an outer peripheral portion has been proposed.

PTL 1 discloses a composite substrate which is a substrate used for an acoustic wave device and includes a support substrate, a piezoelectric substrate, and an adhesive layer that bonds the support substrate and the piezoelectric substrate. In the composite substrate, with a surface of the piezoelectric substrate on a side that is bonded to the support substrate being defined as a first surface and an opposite to the first surface being defined as a second surface, the piezoelectric substrate is formed such that the first surface is on the inside of the second surface when the first surface is projected onto the second surface in a direction perpendicular to the second surface. That is, the outer peripheral surface is formed so that the outer periphery becomes larger toward the outer peripheral side of the piezoelectric substrate.

### CITATION LIST

### Patent Literature

PTL 1: WO 2011/013553

### SUMMARY OF INVENTION

### Technical Problem

However, in the conventional method, the piezoelectric material substrate and the support substrate are materials differing from each other, and the piezoelectric material substrate and the support substrate are subjected to grinding removal with the same grindstone; thus, it is not possible to select a grindstone suitable for each of the materials, and breakage or cracking occurs, resulting in a decrease in yield. In addition, an upper surface of the outer peripheral portion of the support substrate becomes a ground surface, the mechanical strength is weak, and breakage or cracking occurs, resulting in a decrease in yield.

An object of the present invention is to provide, for instance, a method for manufacturing a joined body that is less susceptible to processing breakage or cracking even when an outer peripheral portion is processed and improves a yield, and the like.

### Solution to Problem

In order to solve the above problems, the present invention provides a method for manufacturing a joined body, the method including: an outer peripheral processing step of forming an outer peripheral processed portion, ground inward from an edge portion along a main surface of one of a piezoelectric material substrate and a support substrate; a joining step of joining one of the piezoelectric material substrate and the support substrate, which is formed thereon with the outer peripheral processed portion, to a main surface of the other one, with a main surface side of the one of the piezoelectric material substrate and the support substrate serving as a joining surface side; and a thinning step of thinning the joined piezoelectric material substrate.

Here, in the outer peripheral processing step, a cross-sectional shape can be a rectangular shape, an R shape, or a shape inclined with respect to the main surface.

In addition, roughness of the main surface of each of the piezoelectric material substrate and the support substrate before the outer peripheral processing step is 0.2 nm to 0.5 nm as an arithmetic average roughness Ra, and roughness of a surface of the outer peripheral processed portion formed in the outer peripheral processing step can be 100 nm or more and 200 nm or less as the arithmetic average roughness Ra.

Furthermore, the outer peripheral processing step can be performed to form an outer peripheral processed portion having a width of 0.5 mm or more and 2 mm or less when viewed from above.

In addition, the present invention provides a joined body including a piezoelectric layer and a support substrate joined to the piezoelectric layer, in which the support substrate has an outer peripheral portion in which a main surface of the support substrate is exposed outside a region joined to the piezoelectric layer, and the outer peripheral portion is a mirror surface.

### Advantageous Effects of Invention

According to the present invention, it is possible to provide a method for manufacturing a joined body that is less susceptible to processing breakage or cracking even when an outer peripheral portion is processed and improves a yield, and the like.

### BRIEF DESCRIPTION OF DRAWINGS

FIG. 1 is a view illustrating a joined body of the present embodiment.

FIG. 2 is a flowchart illustrating a method for manufacturing a joined body.

FIGS. 3A to 3F are views illustrating states of outer peripheral portions of piezoelectric material substrates and support substrates.

FIGS. 4A to 4E are views illustrating cross-sectional shapes of outer peripheral processed portions.

FIG. 5 illustrates a joined body polished by a conventional polishing method.

### DESCRIPTION OF EMBODIMENTS

Hereinafter, an embodiment of the present invention will be described in detail with reference to the accompanying drawings.

### <Description of Configuration of Joined Body>

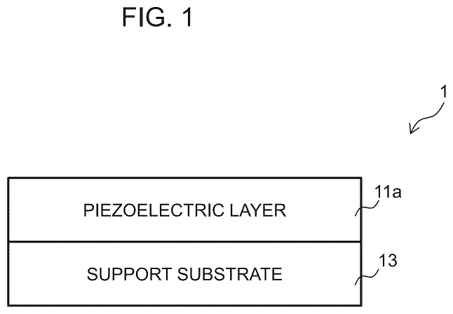

FIG. 1 is a view illustrating a joined body 1 of the present embodiment.

The illustrated joined body 1 has a structure in which a piezoelectric layer 11a and a support substrate 13 are stacked from above in the drawing.

The piezoelectric layer 11a is a layer formed of a piezoelectric material. The piezoelectric material is selected for an application in which the joined body 1 is used. The piezoelectric material is, for example, LiNbO₃ (LN) or LiTaO₃ (LT), but is not limited thereto, and silicon (Si), gallium arsenide (GaAs), silicon carbide (SiC), gallium nitride (GaN), zinc oxide (ZnO), a solid solution ceramic (PZT), or the like is appropriately selected.

The support substrate 13 serves as a support for the entire joined body 1. In addition, the support substrate 13 is joined to the piezoelectric layer 11a. Any suitable substrate can be used as the support substrate 13. The support substrate 13 may be composed of a single crystal, may be composed of a polycrystal, or may be a composite in which a layer of a polycrystal is provided on a single crystal. In addition, the support substrate 13 may be composed of a metal.

The material constituting the support substrate 13 is preferably selected from the group consisting of silicon, sialon, sapphire, cordierite, mullite, glass, quartz, crystal, alumina, SUS, an iron-nickel alloy (42 alloy), and brass. A thickness of the support substrate 13 is, for example, 0.2 to 1 mm, and any other appropriate thickness can be adopted.

The silicon may be monocrystalline silicon, polycrystalline silicon, or high-resistance silicon. In addition, the support substrate 13 may be Silicon on Insulator (SOI).

Typically, the sialon is a ceramic obtained by sintering a mixture of silicon nitride and alumina, and has, for example, a composition represented by Si_{6-w}Al_{w}O_{w}N_{8-w}. Specifically, sialon has a composition in which alumina is mixed in silicon nitride, and w in the formula represents a mixing ratio of alumina. w is preferably 0.5 or more and 4.0 or less.

Typically, the sapphire is a single crystal having a composition of Al₂O₃, and the alumina is a polycrystal having a composition of Al₂O₃. The alumina is preferably translucent alumina.

Typically, the cordierite is a ceramic having a composition of 2MgO·2Al₂O₃·5SiO₂, and the mullite is a ceramic having a composition in a range of 3Al₂O₃·2SiO₂ to 2Al₂O₃·SiO₂.

### <Device>

The structure of the illustrated joined body 1 can be used as structures of various devices. Examples of the device include a high frequency device, a power semiconductor, a semiconductor laser, a surface acoustic wave (SAW) filter, and a thin film piezoelectric micro electro mechanical systems (MEMS).

### <Description of Method for Manufacturing Joined Body 1>

Next, a method for manufacturing a joined body 1 will be described.

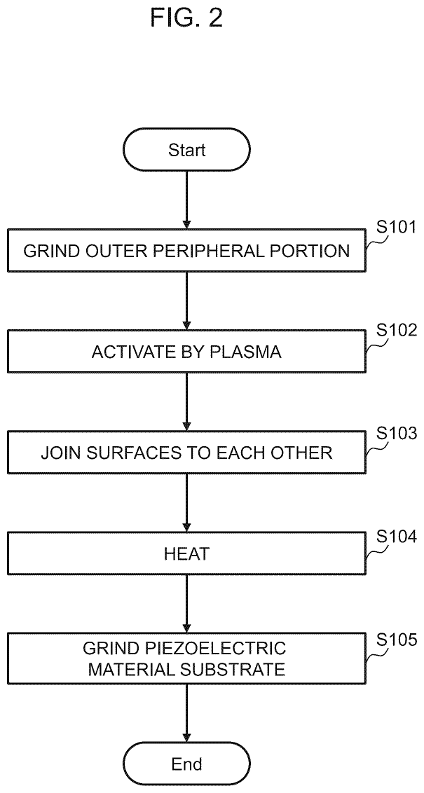

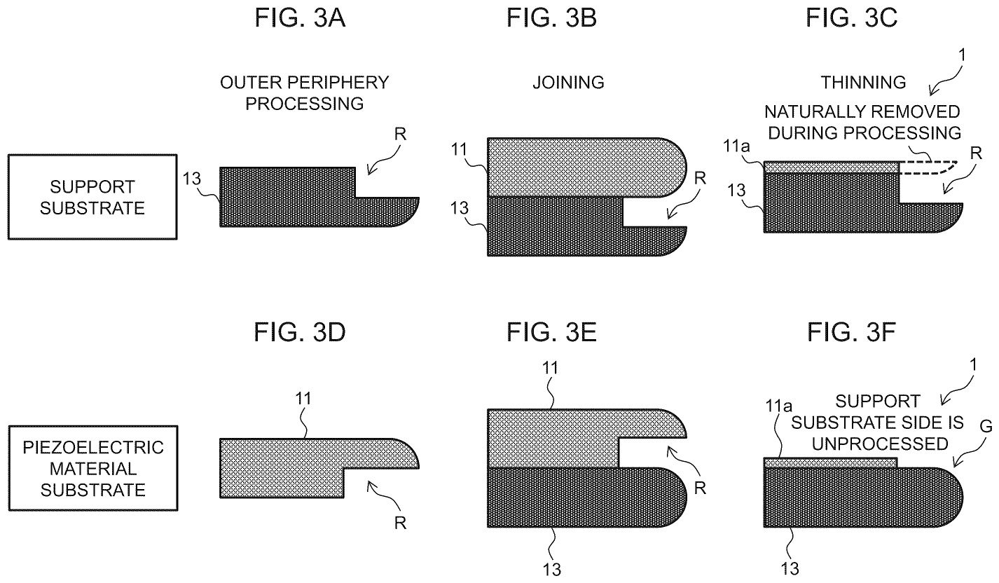

FIG. 2 is a flowchart illustrating a method for manufacturing a joined body 1. In addition, FIGS. 3A to 3F are views illustrating states of outer peripheral portions of piezoelectric material substrates 11 and support substrates 13.

First, the piezoelectric material substrate 11 and the support substrate 13 are prepared. Then, an outer peripheral processed portion R ground inward from an edge portion along a main surface is formed on one of the piezoelectric material substrate 11 and the support substrate 13 (step 101: outer peripheral processing step).

FIG. 3A illustrates a case where the outer peripheral processed portion R is formed on the support substrate 13 in the outer peripheral processing step of Step 101. In this case, the outer peripheral processed portion R is ground inward from the edge portion along the main surface of the support substrate 13 so as to have a rectangular cross-sectional shape.

In addition, FIG. 3D illustrates a case where the outer peripheral processed portion R is formed on the piezoelectric material substrate 11 in the outer peripheral processing step of step 101. Also in this case, the outer peripheral processed portion R is ground inward from the edge portion along the main surface of the piezoelectric material substrate 11 to form a rectangular cross-sectional shape.

In the present embodiment, roughness of the main surface of each of the piezoelectric material substrate 11 and the support substrate 13 before the outer peripheral processing step is 0.2 nm to 0.5 nm as an arithmetic average roughness Ra, and roughness of a surface of the outer peripheral processed portion formed in the outer peripheral processing step is 100 nm or more and 200 nm or less as the arithmetic average roughness Ra. That is, the surface of the piezoelectric material substrate 11 or the support substrate 13 before the outer peripheral processing step is a mirror surface, and an arithmetic average roughness Ra thereof is about 0.2 nm to 0.5 nm, which is significantly small. On the other hand, the outer peripheral processed portion R after the outer peripheral processing step becomes rough by grinding, and an arithmetic average roughness Ra thereof becomes larger than that before the outer peripheral processing step, and is 100 nm or more and 200 nm or less as Ra.

In addition, in the outer peripheral processing step, the outer peripheral processed portion R is preferably formed to have a width of 0.5 mm or more and 2 mm or less when viewed from above (in the thickness direction of the piezoelectric material substrate 11 or the support substrate 13). When the width is 0.5 mm or more, a non-bonded portion between the piezoelectric material substrate 11 and the support substrate 13 is easily and sufficiently removed, which is preferable. In addition, when the width of the outer peripheral processed portion when viewed from above is 2 mm or less, an area that can be sufficiently used as the joined body 1 is secured.

Next, each of the surfaces of the piezoelectric material substrate 11 and the support substrate 13 is activated by plasma (step 102: activation step). As the plasma, Ar plasma can be used.

Further, the surfaces of the piezoelectric material substrate 11 and the support substrate 13 after the activation process are joined to each other (step 103: joining step). The joining is performed, for example, by bringing the surfaces of the piezoelectric material substrate 11 and the support substrate 13 into contact with each other and pressing the surfaces at a predetermined pressure in an ambient temperature environment. As a result, the piezoelectric material substrate 11 and the support substrate 13 are joined.

FIG. 3B illustrates a case where the outer peripheral processed portion R is joined to the piezoelectric material substrate 11 when the outer peripheral processed portion R is formed on the support substrate 13 as illustrated in FIG. 3A. In this case, the support substrate 13 is joined to the piezoelectric material substrate 11 with a side where the outer peripheral processed portion R is formed as a joining surface side.

In addition, FIG. 3E illustrates a case where the outer peripheral processed portion R is joined to the support substrate 13 when the outer peripheral processed portion R is formed on the piezoelectric material substrate 11 as illustrated in FIG. 3D. Also in this case, the piezoelectric material substrate 11 is joined to the support substrate 13 with a side where the outer peripheral processed portion R is formed as a joining surface side.

Therefore, in the joining step, one of the piezoelectric material substrate 11 and the support substrate 13 on which the outer peripheral processed portion R is formed is joined to the other main surface with the main surface side on which the outer peripheral processed portion R is formed as the joining surface side.

Then, the joined piezoelectric material substrate 11 and support substrate 13 are heated (step 104: heating step). For example, the joined piezoelectric material substrate 11 and support substrate 13 are placed in a heating apparatus such as an oven and heated at a predetermined temperature for a predetermined time.

Note that the heating step can also be regarded as a step of annealing the joined piezoelectric material substrate 11 and support substrate 13 (annealing step).

Next, the piezoelectric material substrate 11 after joining is thinned. The piezoelectric material substrate 11 is thinned by grinding (step 105: thinning step). As a result, the piezoelectric layer 11a illustrated in FIG. 1 is formed. The grinding can be performed by a known method using a grinding machine.

FIG. 3C is a view illustrating a case where the piezoelectric material substrate 11 is thinned by grinding when the outer peripheral processed portion R is formed on the support substrate 13 as illustrated in FIG. 3A. In this case, the piezoelectric material substrate 11 adjacent to the outer peripheral processed portion R formed on the support substrate 13 can be naturally removed during processing. The remaining portion becomes the piezoelectric layer 11a. In this case, the piezoelectric layer 11a is formed in a state of being retracted inward to a location where the outer peripheral processed portion R is formed.

In addition, FIG. 3F is a view illustrating a case where the piezoelectric material substrate 11 is thinned by grinding when the outer peripheral processed portion R is formed on the piezoelectric material substrate 11 as illustrated in FIG. 3D. Also in this case, the piezoelectric layer 11a is formed in a state of being retracted inward to a location where the outer peripheral processed portion R is formed.

Through the above steps, the joined body 1 can be manufactured. Note that it can also be said that the joined body 1 of FIG. 3F includes the piezoelectric layer 11a and the support substrate 13 joined to the piezoelectric layer 11a, the support substrate 13 has an outer peripheral portion G in which a main surface of the support substrate 13 is exposed outside a region joined to the piezoelectric layer 11a, and the outer peripheral portion is a mirror surface. That is, as described above, the surface before the outer peripheral processed portion R is formed on one of the piezoelectric material substrate 11 and the support substrate 13 is a mirror surface, but when the outer peripheral processed portion R is formed, the surface becomes rough. However, in the joined body 1 of FIG. 3F, since the outer peripheral processed portion R is not formed in the outer peripheral portion G where the main surface of the support substrate 13 is exposed, the outer peripheral processed portion R is unprocessed and maintains a mirror surface state. Regarding the mirror surface, as described above, the arithmetic average roughness Ra of the surface of the outer peripheral portion G is about 0.2 nm to 0.5 nm.

In the embodiment described above, the cross-sectional shape of the outer peripheral processed portion R is formed in a rectangular shape, but the present invention is not limited thereto.

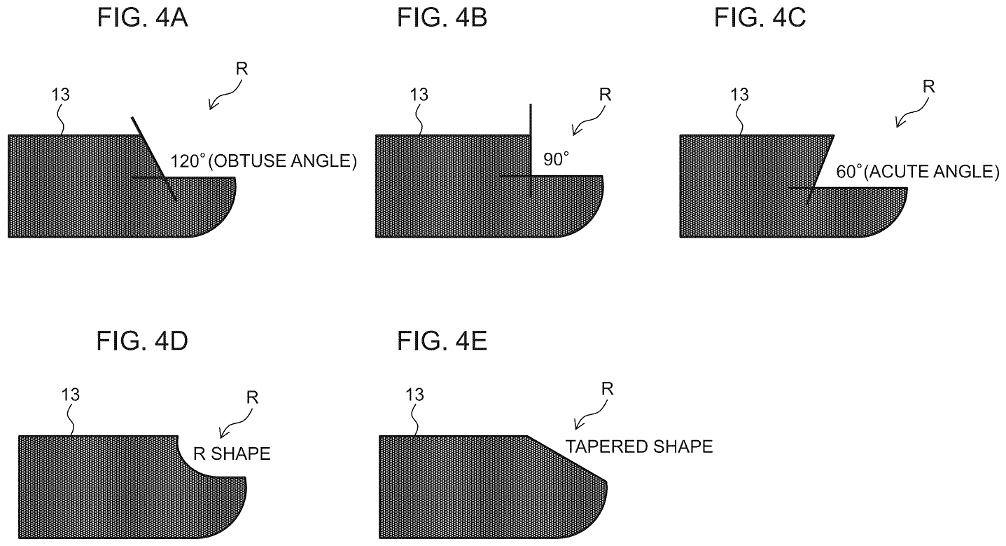

FIGS. 4A to 4E are views illustrating cross-sectional shapes of the outer peripheral processed portions R.

Note that although FIG. 4 illustrates the case of the support substrate 13, the same applies to the piezoelectric material substrate 11.

Among them, FIG. 4A illustrates a case where the cross-sectional shape is a trapezoidal shape. In this case, it can be said that the cross-sectional shape of the outer peripheral processed portion R is a shape in which two straight lines intersect, and the intersection angle is an obtuse angle of 120°.

FIG. 4B illustrates a case where the cross-sectional shape is a rectangular shape. This is similar to the case illustrated in FIG. 3. Also in this case, it can be said that the cross-sectional shape of the outer peripheral processed portion R is a shape in which two straight lines intersect, and the intersection angle is 90°.

FIG. 4C illustrates a case where the cross-sectional shape is a parallelogram shape. Also in this case, it can be said that the cross-sectional shape of the outer peripheral processed portion R is a shape in which two straight lines intersect, and the intersection angle is an acute angle of 60°.

FIG. 4D illustrates a case where the cross-sectional shape is an R shape. In this case, it can also be said that the cross-sectional shape of the outer peripheral processed portion R is a curved shape.

FIG. 4E illustrates a case where the cross-sectional shape is a tapered shape. In this case, it can also be said that the cross-sectional shape of the outer peripheral processed portion R is a shape in which one straight line intersects the main surface. In addition, it can also be said that the cross-sectional shape of the outer peripheral processed portion R is a shape inclined with respect to the main surface.

These shapes can be formed by rotating a grindstone whose outer periphery corresponds to these shapes and grinding the piezoelectric material substrate 11 or the support substrate 13.

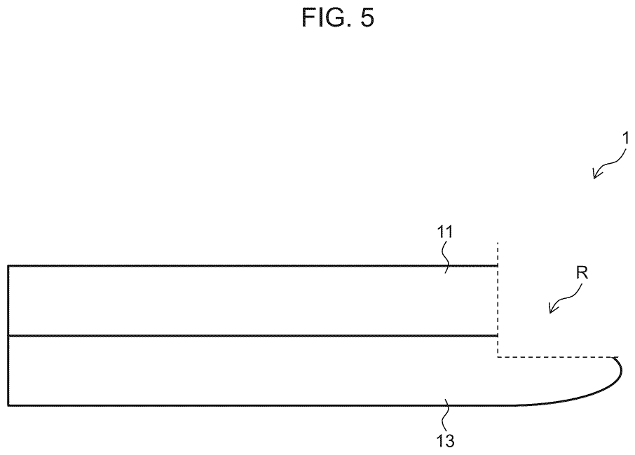

FIG. 5 illustrates a joined body 1 polished by a conventional processing method.

As illustrated, in the conventional grinding method, grinding is performed from an upper surface of the piezoelectric material substrate 11 to a depth of a part of the support substrate 13 to form the outer peripheral processed portion R. In this case, since the piezoelectric material substrate 11 and the support substrate 13 are ground and removed with the same grindstone, it is not possible to select a grindstone suitable for each material, and breakage or cracking occurs, resulting in a decrease in yield.

On the other hand, in the present embodiment, it is possible to select a grindstone suitable for the material of each of the piezoelectric material substrate 11 and the support substrate 13, such that the joined body 1 is less likely to be broken or cracked. Furthermore, a processing time is shortened and a lifespan of the grindstone is prolonged as compared with the conventional processing method. That is, conventionally, the entire piezoelectric material substrate 11 has been processed, but in the present method, it is sufficient to subject the surface of one of the piezoelectric material substrate 11 and the support substrate 13 to processing by, for example, about 20 μm.

In addition, as illustrated in FIGS. 3D to 3F, when the piezoelectric material substrate 11 is ground to form the outer peripheral processed portion R, the upper surface of the outer peripheral portion of the support substrate 13 does not become a ground surface. Therefore, the mechanical strength of the joined body 1 is maintained, and breakage or cracking hardly occurs, and thus, the yield is improved. In addition, as described above, in the outer peripheral portion G, the main surface of the support substrate 13 is exposed, and the mirror surface state is maintained. Therefore, the mechanical strength of the joined body 1 increases, and breakage or cracking is less likely to occur in the outer peripheral portion G.

### Examples

As the piezoelectric material substrate 11, a 42Y-cut black LiTaO₃ (LT) substrate having a thickness of 0.5 mm and both surfaces polished to a mirror surface (an arithmetic average roughness Ra is 0.2 nm to 0.5 nm) was prepared. In addition, a high-resistance (≥2 kΩ·cm) Si substrate having a thickness of 0.5 mm was prepared as the support substrate 13.

Next, edge processing was performed on the LT substrate side or the Si substrate side at a width of 2.0 mm and a depth of 20 μm, and contamination during processing was removed by cleaning. By the edge processing, an outer peripheral processed portion R was formed (outer peripheral processing step). A surface roughness Ra of the outer peripheral processed portion R was 180 nm.

The surfaces of the LT substrate and the Si substrate were each subjected to Ar activation (activation step), and then joined (joining step). For the purpose of increasing the joining strength, the joined substrates were put in an oven at 100° C. and heated for 20 hours (heating step). An LT surface of the joined substrate taken out of the oven was thinned to 5 μm by grinding. Thereafter, the LT surface was thinned to 1 μm by polishing processing (thinning step), but abnormalities such as peeling and scratches of the LT substrate, chipping of the processed portion, and cracking did not occur.

Although the present embodiment has been described above, the technical scope of the present invention is not limited to the scope described in the above embodiment. It is apparent from the description of the claims that various modifications or improvements are added to the above embodiment within the technical scope of the present invention.

### REFERENCE SIGNS LIST

1 Joined body
11 Piezoelectric material substrate
11a Piezoelectric layer
13 Support substrate
R Outer peripheral processed portion
G Outer peripheral portion

1. A method for manufacturing a joined body, the method comprising:
an outer peripheral processing step of forming an outer peripheral processed portion, ground inward from an edge portion along a main surface of one of a piezoelectric material substrate and a support substrate;
a joining step of joining one of the piezoelectric material substrate and the support substrate, which is formed thereon with the outer peripheral processed portion, to a main surface of the other one, with a main surface side of the one of the piezoelectric material substrate and the support substrate serving as a joining surface side; and
a thinning step of thinning the joined piezoelectric material substrate.

2. The method for manufacturing a joined body according to claim 1, wherein the outer peripheral processing step is performed so that a cross-sectional shape is a rectangular shape, an R shape, or a shape inclined with respect to the main surface.

3. The method for manufacturing a joined body according to claim 1, wherein roughness of the main surface of each of the piezoelectric material substrate and the support substrate before the outer peripheral processing step is 0.2 nm to 0.5 nm as an arithmetic average roughness Ra, and roughness of a surface of the outer peripheral processed portion formed in the outer peripheral processing step is 100 nm or more and 200 nm or less as the arithmetic average roughness Ra.

4. The method for manufacturing a joined body according to claim 1, wherein in the outer peripheral processing step, the outer peripheral processed portion is formed to have a width of 0.5 mm or more and 2 mm or less when viewed from above.

5. A joined body comprising:
a piezoelectric layer; and
a support substrate joined to the piezoelectric layer,
wherein the support substrate has an outer peripheral portion in which a main surface of the support substrate is exposed outside a region joined to the piezoelectric layer, and the outer peripheral portion is a mirror surface.
